(19) United States
(12) Patent Application Publication
(10) Pub. No.: US 2021/0242384 A1
(43) Pub. Date: Aug. 5, 2021

(54) LIGHT-EMITTING DIODE CHIP, DISPLAY PANEL, ELECTRONIC DEVICE

(71) Applicant: CHONGQING KONKA PHOTOELECTRIC TECHNOLOGY RESEARCH INSTITUTE CO., LTD., Chongqing (CN)

(72) Inventors: Ya-Wen LIN, Chongqing (CN); Chia-Hung HUANG, Chongqing (CN); Shun Kuei YANG, Chongqing (CN); KUO-TUNG HUANG, Chongqing (CN)

(21) Appl. No.: 17/235,661

(22) Filed: Apr. 20, 2021

Related U.S. Application Data
(63) Continuation of application No. PCT/CN2019/130525, filed on Dec. 31, 2019.

(51) Int. Cl. H01L 33/62; H01L 25/075; H01L 33/06; H01L 33/00; H01L 33/40

(52) U.S. Cl. CPC H01L 33/62; H01L 25/0753; H01L 33/405; H01L 33/0008; H01L 33/06

(57) ABSTRACT

A light-emitting diode (LED) chip is provided. The LED chip includes a first semiconductor layer, a second semiconductor layer, a first electrode electrically connected with the first semiconductor layer, and a second electrode electrically connected with the second semiconductor layer. The first electrode is in an annular shape and surrounds the second electrode. The first electrode and the second electrode cooperate to define a first channel therebetween. The first channel is in an annular shape. The first electrode defines at least one second channel therein. The at least one second channel extends through an inner side and an outer side of the first electrode and communicates with the first channel. A communication between the first channel and the second channel facilitates solder volatiles during soldering the LED chip, and potential short circuits can be further avoided. A display panel and an electronic device are further provided.

### CROSS-REFERENCE TO RELATED APPLICATION(S)

This application is a continuation of International Application No. PCT/CN2019/130525, filed on Dec. 31, 2019, which is hereby incorporated by reference in its entirety.

### TECHNICAL FIELD

The present disclosure relates to the field of display technology, and particularly to a light-emitting diode chip, a display panel, and an electronic device.

### BACKGROUND

As current mode light-emitting devices, micro light-emitting diodes (mic-LEDs) are widely used in display devices due to their several advantages such as active light emission, high response speed, wide viewing angle, rich colors, high brightness, and low power consumption. A display device using micro LEDs generally includes a substrate and LED pixel units arranged in an array on the substrate. Pixel circuits are arranged on the substrate for driving the LED pixel units to emit lights. The pixel circuits adopt devices made of metal materials.

In the related art, a circular electrode has an advantage of no directionality, but an enclosed space is formed between two electrodes. Generally, electrodes are coated with flux during the backplane manufacturing process, and common fluxes include aluminum tin soldering flux, stainless steel lead-free soldering flux, high-efficiency Al—Cu soldering liquid flux, etc. Since the flux is an organic volatile substance, the use of the flux in a circular chip will cause flux residue, which will easily affect the conductivity and reduce the reliability of the backplane.

### SUMMARY

In view of this, it is necessary to provide a LED chip, a display panel, and an electronic device, so as to reduce flux residue, and further avoid potential short circuits are further avoided.

To solve the above technical problems, the technical solutions of the present disclosure include the following.

In a first aspect, a LED chip is provided. The LED chip includes a first semiconductor layer, a second semiconductor layer, a first electrode electrically connected with the first semiconductor layer, and a second electrode electrically connected with the second semiconductor layer. The first electrode is in an annular shape and surrounds the second electrode. The first electrode and the second electrode cooperate to define a first channel therebetween. The first channel is in an annular shape. The first electrode defines at least one second channel therein. The at least one second channel extends through an inner side and an outer side of the first electrode and communicates with the first channel.

In a second aspect, a display panel is provided. The display panel includes a backplane and the LED chip mounted on the backplane.

The backplane is provided with a bonding electrode matched with the first electrode and the second electrode of the LED chip. The LED chip is flip-mounted on the backplane after being bonded with the bonding electrode through the first electrode and the second electrode.

In a third aspect, an electronic device is provided. The electronic device includes a housing and the display panel disposed on the housing.

In the above-mentioned LED chip, the display panel, and the electronic device, since the first electrode is in an annular shape and surrounds the second electrode, the first electrode and the second electrode cooperate to define an annular first channel therebetween. The first electrode defines at least one second channel therein. The at least one second channel extends through an inner side and an outer side of the first electrode and communicates with the first channel. When soldering the LED chip, the flux can be discharged out of the LED chip via the first channel and the second channel, such that the flux residue can be reduce and potential short circuits can be further avoided.

### BRIEF DESCRIPTION OF THE DRAWINGS

Exemplary implementations of the present disclosure will be described in detail below with reference to the accompanying drawings to make the above-mentioned features and advantages of the present disclosure more clear to those skilled in the art, in which:

FIG. 1 is a schematic top view of a LED chip according to an implementation of the present disclosure.

FIG. 2 is a schematic cross-sectional view taken along A1-A2 of FIG. 1.

FIG. 3 is a schematic cross-sectional view taken along A3-A4 of FIG. 1.

FIG. 4 is a schematic top view of a single LED chip of the present disclosure.

FIG. 5 is a schematic top view of a LED chip according to an implementation of the present disclosure.

FIG. 6 is a schematic cross-sectional view taken along B1-B2 of FIG. 5.

FIG. 7 is a schematic top view of a LED chip according to an implementation of the present disclosure.

FIG. 8 is a schematic cross-sectional view taken along C1-C2 of FIG. 7.

FIG. 9 is a schematic cross-sectional view taken along C3-C4 of FIG. 7.

FIG. 10 is a schematic top view of a LED chip according to an implementation of the present disclosure.

FIG. 11 is a schematic cross-sectional view taken along D1-D2 of FIG. 10.

FIG. 12 is a schematic cross-sectional view taken along D3-D4 of FIG. 10.

FIG. 13 is a schematic top view of a LED chip according to an implementation of the present disclosure.

FIG. 14 is a schematic cross-sectional view taken along E1-E2 of FIG. 13.

FIG. 15 is a schematic view of a display panel including the LED chip illustrated in FIG. 1.

FIG. 16 is a schematic view of an electronic device including the display panel illustrated in FIG. 15.

### DETAILED DESCRIPTION OF ILLUSTRATED IMPLEMENTATIONS

In order to understand implementations of the present disclosure more clearly and accurately, a detailed description will now be given with reference to the accompanying drawings. The accompanying drawings illustrate examples of implementations of the present disclosure, in which identical reference signs refer to identical features. It can be understood that the scale illustrated in the drawings is not for actual implementations of the present disclosure, which is only for illustration and not drawn according to the original size.

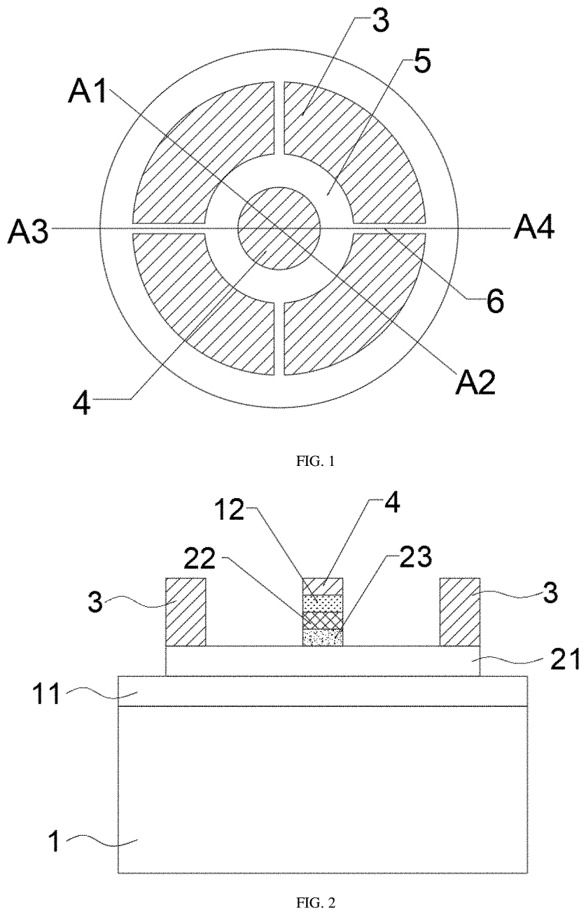

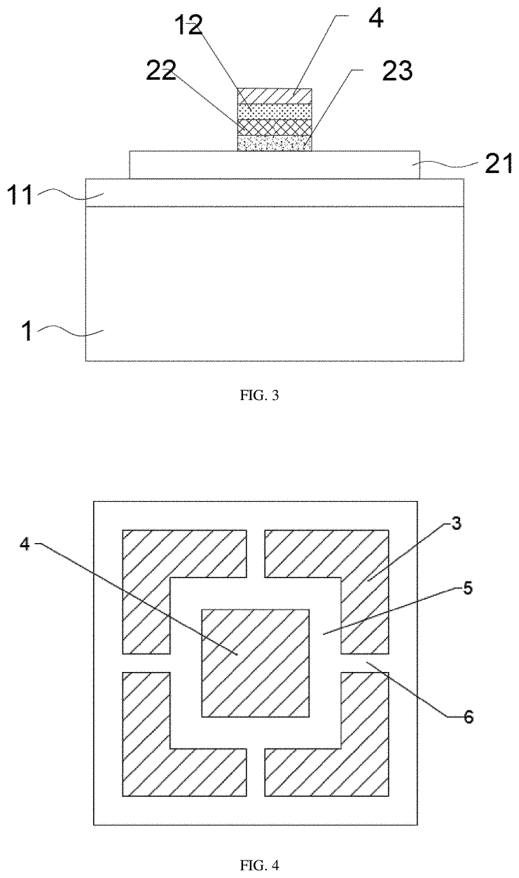

FIG. 1 is a schematic top view of a light-emitting diode (LED) chip 72 of an implementation. FIG. 2 is a schematic cross-sectional view taken along A1-A2 of FIG. 1. FIG. 3 is a schematic cross-sectional view taken along A3-A4 of FIG. 1. In this implementation, the LED chip 72 includes a first semiconductor layer 21, a second semiconductor layer 22, a first electrode 3, and a second electrode 4. In implementations, the LED chip 72 is formed on a substrate layer 1. In this implementation, the LED chip 72 further includes a current diffusion layer 12, an undoped semiconductor layer 11, and a quantum well layer 23. As an example, the undoped semiconductor layer 11, the first semiconductor layer 21, the quantum well layer 23, the second semiconductor layer 22, and the current diffusion layer 12 are stacked in sequence from the substrate layer 1.

The first electrode 3 is disposed on a side of the first semiconductor layer 21 close to the second semiconductor layer 22. The first electrode 3 is electrically connected with the first semiconductor layer 21. The first electrode 3 is in an annular shape. In this implementation, the first electrode 3 an N-type electrode.

The second electrode 4 is electrically coupled with the second semiconductor layer 22. In this implementation, the second electrode 4 is a P-type electrode. The second electrode 4 is located within a region surrounded by an inner peripheral wall of the first electrode 3. The geometric center of the second electrode 4 coincides with a geometric center of an outer edge or an inner edge of the first electrode 3. In another implementation, the geometric center of a top surface of the second electrode 4 coincides with a geometric center of a top surface of the first electrode 3. An end of the first electrode 3 away from the first semiconductor layer 21 and an end of the second electrode 4 away from the second semiconductor layer 22 are located on the same plane. The quantum well layer 23, the current diffusion layer 12, and the second semiconductor layer 22 are disposed below the second electrode 4. The current diffusion layer 12, the second semiconductor layer 22, and the quantum well layer 23 are sequentially stacked on the first semiconductor layer 21.

In this implementation, each of the first electrode 3 and the second electrode 4 is a metal reflective electrode. By setting the first electrode 3 and the second electrode 4 as metal reflective electrodes, lights emitted toward the first electrode 3 or the second electrode 4 can be reflected to return to a light-emitting surface, the luminous efficiency of the LED chip 72 is improved, and the power consumption of the LED chip 72 can be reduced. As an option, the metal reflective electrode can be a reflective metal laminate made of Cr, Al, Ti, Pt, Au, etc., which is not limited herein.

An annular first channel 5 is defined between the first electrode 3 and the second electrode 4. The first electrode 3 defines at least one second channel 6 therein. The at least one second channel 6 extends through an inner side and an outer side of the first electrode 3 and communicates with the first channel 5. The second channel 6 also extends from the first electrode 3 to a plane on which the second electrode 4 grows. Alternatively, the second channel 6 also extends from the first electrode 3 to a plane where the second electrode 4 locates.

In this implementation, the at least one second channel 6 can be but is not limited to four second channels 6. In implementations, the at least one second channel 6 can be one second channel 6, two second channels 6, three second channels 6, and five second channels 6, etc., which are not limited herein.

The first channel 5 is annular. The second channel 6 extends through the inner side and the outer side of the first electrode 3 and communicates with the first channel 5.

In this implementation, the first channel 5 has a depth which can be but not limited to the same as the second channel 6. In implementations, the second channel 6 may have a bottom which is in a slope shape. A higher end of the bottom of the second channel 6 is jointed with a bottom of the first channel 5, thereby facilitating exhaust of solder volatiles in the first channel 5 and the second channel 6. Of course, in this implementation, a cross section of the second channel 6 may have but not limited to a rectangular shape. In implementations, the cross section of the second channel 6 may also has a trapezoid shape, an arc shape, or other shapes, which is not limited herein.

The substrate layer 1 is disposed at a bottom of the LED chip 72. The substrate layer 1 is cylindrical. In this implementation, the substrate layer 1 may be made of but not limited to sapphire (Al₂O₃). In implementations, the substrate layer 1 may also be made of a material such as silicon (Si), silicon carbide (SiC), etc., which is not limited here.

The quantum well layer 23 is sandwiched between the first semiconductor layer 21 and the second semiconductor layer 22. The quantum well layer 23 and the second semiconductor layer 22 each have a cylindrical shape and are stacked on the first semiconductor layer 21 in sequence. The second channel 6 also extends through the inner side and the outer side of the first electrode 3.

The undoped semiconductor layer 11, the first semiconductor layer 21, the quantum well layer 23, the second semiconductor layer 22, and the current diffusion layer 12 are sequentially stacked on the substrate layer 1.

In an implementation, the first semiconductor layer 21 is an N-type semiconductor. The N-type semiconductor is also called an electronic semiconductor. The N-type semiconductor is an impurity semiconductor in which concentration of free electrons is much greater than that of holes. Electron holes are majority carriers in the N-type semiconductor. The N-type semiconductor is formed by introducing donor-type impurities. Impurities are doped into pure semiconductor materials to enable impurity energy levels to be induced in the forbidden band. If an impurity atom can contribute electrons, the energy level of the impurity atom is the donor level, and the semiconductor is an N-type semiconductor. For example, when arsenic impurity of group V is added into a semiconductor of silicon of group IV, the conductivity and the conductivity type of the semiconductor can be changed. For the N-type semiconductor (for example, silicon or germanium doped with group VA elements such as phosphorus, arsenic, antimony, bismuth, etc.), electrons are excited into the conduction band and become the majority carriers. There are also some solids that are always N-type semiconductors, such as ZnO, TiO, V₂O₅, MoO₃, and the like.

The second semiconductor layer 22 is a P-type semiconductor. The P-type semiconductor is also called a hole-type semiconductor. The P-type semiconductor is an impurity semiconductor in which concentration of holes is much greater than that of free electrons. The pure silicon crystal is doped with trivalent elements (such as boron) to replace the silicon atoms in the crystal lattice to form a P-type semiconductor. In the P-type semiconductor, holes are majority carriers and free electrons are minority carriers, and the conductivity of the P-type semiconductor mainly depends on the holes. More impurities doped corresponds to a higher concentration of the majority carriers (holes) and a higher conductivity.

FIG. 4 is a top view of a single LED chip 72. It is noted that FIGS. 1 to 3 schematically illustrate only one type of the LED chip 72 that can be implemented. The top-view profile of a single LED chip 72 may also be triangular, rectangular, or hexagonal, etc. The single LED chip 72 can be obtained by dividing with cutting lanes of corresponding shapes according to actual requirements, such that the top-view profile of the LED chip 72 has a corresponding shape. According actual conditions, an outer edge and an inner edge of the first electrode 3 and the second electrode 4 can also be designed to have a regular or irregular shape. In addition, FIG. 2 merely illustrates structures of main film layers of the LED chip 72, the LED chip 72 according to implementations of the present disclosure may also include other functional film layers, which is not limited herein.

In this implementation, the geometric center of the second electrode 4 coincides with the geometric center of the outer edge or the inner edge of the first electrode 3. In another implementation, the geometric center of the top surface of the second electrode 4 coincides with the geometric center of the top surface of the first electrode 3. By designing the outer edge and the inner edge of the first electrode 3 and the second electrode 4 to be circular, it is possible to ensure that no matter how the LED chip 72 rotates, the first electrode 3 and the second electrode 4 are properly aligned with a bonding electrode 73 located at a corresponding position on the backplane 71. As such, an area of an electrical contact region between the first electrode 3 and the second electrode 4 and the bonding electrode 73 is increased, electrical connection performance between the LED chip 72 and the backplane 71 is further improved, and poor electrical contact between the LED chip 72 and the backplane 71 is effectively avoided. In addition, since at least one second channel 6 communicated with the first channel 5 is provided, a communication path between the first electrode 3 and the second electrode 4 is formed through the second channel 6, which facilitates the flux volatilization.

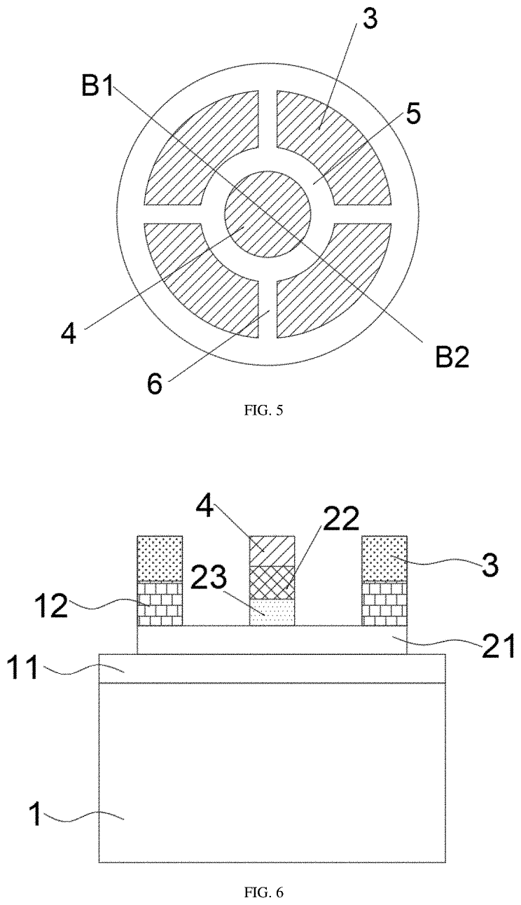

FIG. 5 is a schematic top view of the LED chip 72 according to an implementation. FIG. 6 is a schematic cross-sectional view taken along B1-B2 of FIG. 5. The difference between the LED chip 72 illustrated in FIG. 5 and the LED chip 72 illustrated in FIG. 1 includes the following. In this implementation, the types of first electrode 3 and the second electrode 4 illustrated in FIG. 5 are interchanged with respect to the first electrode 3 and the second electrode 4 illustrated in FIG. 1. That is, in this implementation, the first electrode 3 is a P-type electrode, and the second electrode 4 is an N-type electrode. Accordingly, the first semiconductor layer 21 is a P-type semiconductor layer, and the second semiconductor layer 22 is an N-type semiconductor layer.

In this implementation, the first electrode 3 is disposed on the side of the current diffusion layer 12 away from the first semiconductor layer 21. Both the first electrode 3 and the current diffusion layer 12 have a ring shape. The current diffusion layer 12 is sandwiched between the first semiconductor layer 21 and the first electrode layer 3. The quantum well layer 23 and the second semiconductor layer 22 are provided below the second electrode 4. The quantum well layer 23, the second semiconductor layer 22, and the second electrode 4 are sequentially stacked on the first semiconductor layer 21. An inner edge of a ring structure surrounded by the first electrode 3 and the current diffusion layer 12 close to the second electrode 4 is in contact with an outer edge of the first channel 5 away from the second electrode 4.

The second electrode 4 is disposed on a side of the second semiconductor layer 22 away from the first semiconductor layer 21. The second electrode 4 is located within the region surrounded by the peripheral wall of the first electrode 3. The geometric center of the second electrode 4 coincides with the geometric center of the outer edge or the inner edge of the first electrode 3. In another implementation, the geometric center of the top surface of the second electrode 4 coincides with the geometric center of the top surface of the first electrode 3. The end of the first electrode 3 away from the first semiconductor layer 21 and the end of the second electrode 4 away from the second semiconductor layer 22 are located on the same plane.

The first electrode 3 and the second electrode 4 cooperate to define the annular first channel 5 therebetween. The first electrode 3 defines the at least one second channel 6 therein. The at least one second channel 6 extends through the inner side and the outer side of the first electrode 3 and communicates with the first channel 5. The second channel 6 extends from the first electrode 3 to a plane on which the second electrode 4 grows.

In this implementation, the at least one second channel 6 can be but is not limited to four second channels 6. In implementations, the at least one second channel 6 can be one second channel 6, two second channels 6, three second channels 6, and five second channels 6, etc., which are not limited herein.

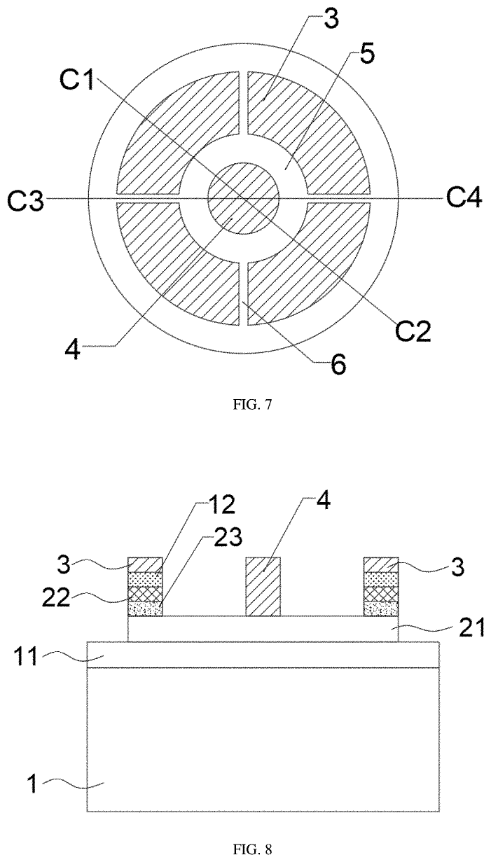

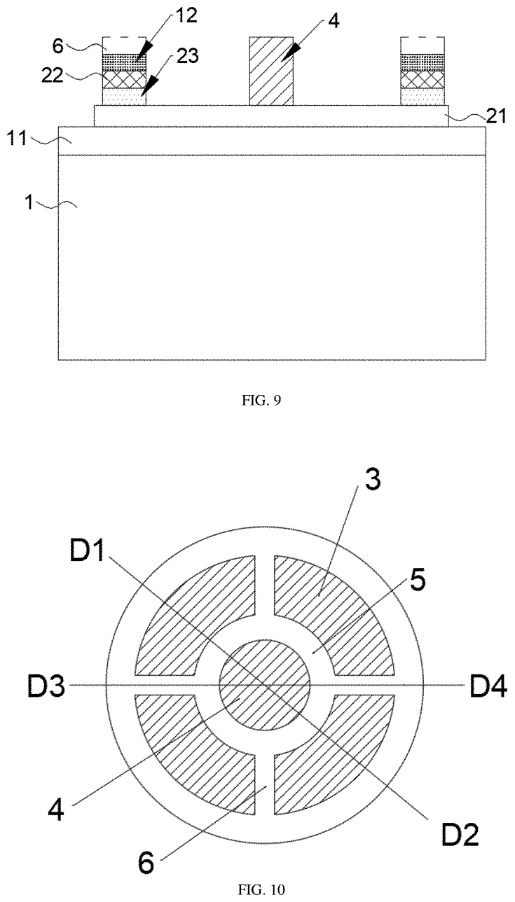

FIG. 7 is a schematic top view of the LED chip 72 according to an implementation. FIG. 8 is a schematic cross-sectional view taken along C1-C2 of FIG. 7. FIG. 9 is a schematic cross-sectional view taken along C3-C4 of FIG. 7. The difference between the LED chip 72 illustrated in FIG. 7 and the LED chip 72 illustrated in FIG. 1 includes the following. In this implementation, the types of the first electrode 3 and the second electrode 4 illustrated in FIG. 7 are interchanged with respect to the first electrode 3 and the second electrode 4 illustrated in FIG. 1. That is, in this implementation, the first electrode 3 is a P-type electrode, and the second electrode 4 is an N-type electrode. Accordingly, the first semiconductor layer 21 is an N-type semiconductor layer, and the second semiconductor layer 22 is a P-type semiconductor layer.

In this implementation, each of the second semiconductor layer 22, the quantum well layer 23, and the current diffusion layer 12 is in a ring shape. An inner edge, close to the second electrode 4, of a ring structure surrounded by the first semiconductor layer 21, the second semiconductor layer 22, the quantum well layer 23, and the current diffusion layer 12 is in contact with an outer edge of the first channel 5 close to the second electrode 4.

The first electrode 3 is disposed on the second semiconductor layer 22. The first electrode 3 is electrically coupled with the second semiconductor layer 22. The first electrode 3 is disposed on the side of the first semiconductor layer 21 facing the second semiconductor layer 22. The first electrode 3 has a ring structure.

The second electrode 4 is disposed on the first semiconductor layer 21. The second electrode 4 is electrically coupled with the first semiconductor layer 21. The second electrode 4 is disposed on a side of the first semiconductor layer 21 away from the substrate layer 1. The second electrode 4 is a P-type electrode. The second electrode 4 is located within a region surrounded by the inner peripheral wall of the first electrode 3. The geometric center of the second electrode 4 coincides with the geometric center of the outer edge or the inner edge of the first electrode 3. In another implementation, the geometric center of the top surface of the second electrode 4 coincides with the geometric center of the top surface of the first electrode 3. The end of the first electrode 3 away from the first semiconductor layer 21 and the end of the second electrode 4 away from the second semiconductor layer 22 are located on the same plane.

In this implementation, the first electrode 3 and the second electrode 4 are metal reflective electrodes. The metal reflective electrodes refer to metal electrodes capable of reflecting lights. By setting the first electrode 3 and the second electrode 4 as metal reflective electrodes, the lights emitted toward the first electrode 3 or the second electrode 4 can be reflected to return to the light-emitting surface, the luminous efficiency of the LED chip 72 is improved, and the power consumption of the LED chip 72 can be reduced. As an option, the metal reflective electrode can be a reflective metal laminate made of Cr, A1, Ti, Pt, Au, etc., which is not limited herein.

The first electrode 3 and the second electrode 4 cooperate to define the annular first channel 5 therebetween. The first electrode 3 defines the at least one second channel 6 therein. The least one second channel 6 extends through an inner side and an outer side of the first electrode 3 and communicates with the first channel 5. The second channel 6 also extends from the first electrode 3 to a plane on which the second electrode 4 grows. Alternatively, the second channel 6 also extends from the first electrode 3 to a plane where the second electrode 4 locates.

In this implementation, the at least one second channel 6 can be but is not limited to four second channels 6. In implementations, the at least one second channel 6 can be one second channel 6, two second channels 6, three second channels 6, and five second channels 6, etc., which are not limited herein.

In this implementation, the first channel 5 has a depth which can be but not limited to the same as the second channel 6. In implementations, the second channel 6 may have a bottom which is in a slope shape. The higher end of the bottom of the second channel 6 is jointed with the bottom of the first channel 5, thereby facilitating exhaust of solder volatiles in the first channel 5 and the second channel 6. Of course, in this implementation, the cross section of the second channel 6 may have but not limited to a rectangular shape. In implementations, the cross section of the second channel 6 may also has a trapezoid shape, an arc shape, or other shapes, which is not limited herein.

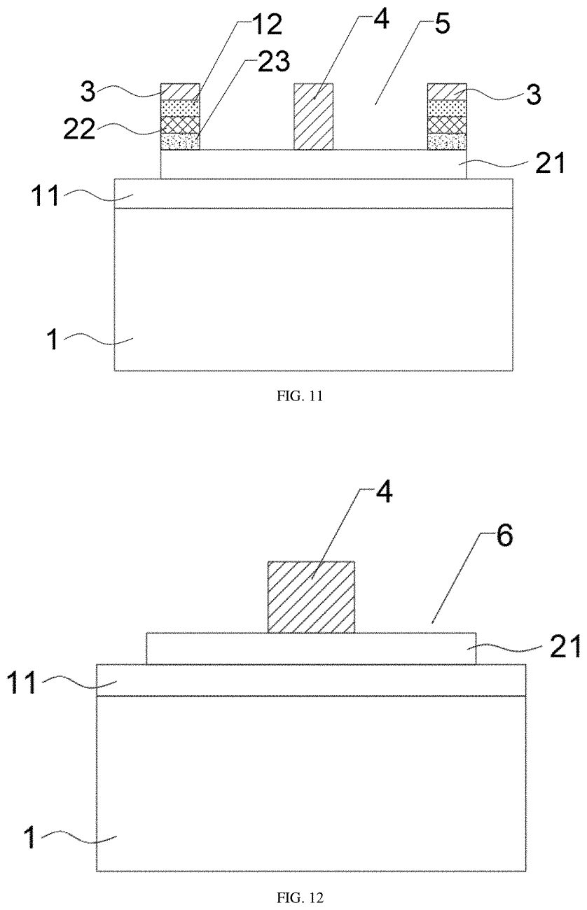

FIG. 10 is a schematic top view of the LED chip 72 according to an implementation. FIG. 11 is a schematic cross-sectional view taken along D1-D2 of FIG. 10. FIG. 12 is a schematic cross-sectional view taken along D3-D4 of FIG. 10. The difference between the LED chip 72 illustrated in FIG. 10 and the LED chip 72 illustrated in FIG. 1 includes the following. In this implementation, the second channel 6 extends through the inner side and the outer side of the first electrode 3 and communicates with the first channel 5. At the same time, the second channel 6 also extends through the first semiconductor layer 21, the second semiconductor layer 22, the quantum well layer 23, and the current diffusion layer 12.

In this implementation, each of the first electrode 3, the second semiconductor layer 22, the quantum well layer 23, and the current diffusion layer 12 has a ring shape.

The first electrode 3 is a P-type electrode. The first electrode 3 is disposed on the second semiconductor layer 22. The first electrode 3 is electrically coupled with the second semiconductor layer 22. The first electrode 3 is disposed on a side of the first semiconductor layer 21 facing the second semiconductor layer 22.

The second electrode 4 is an N-type electrode. The second electrode 4 is disposed on the first semiconductor layer 21. The second electrode 4 is electrically coupled with the first semiconductor layer 21. The second electrode 4 is disposed on the side of the first semiconductor layer 21 away from the substrate layer 1. The second electrode 4 is located within the region surrounded by the inner peripheral wall of the first electrode 3. The geometric center of the second electrode 4 coincides with the geometric center of the outer edge or the inner edge of the first electrode 3. In an implementation, the geometric center of the top surface of the second electrode 4 coincides with the geometric center of the top surface of the first electrode 3. The end of the first electrode 3 away from the first semiconductor layer 21 and the end of the second electrode 4 away from the second semiconductor layer 22 are located on the same plane.

The annular first channel 5 is defined between the first electrode 3 and the second electrode 4. The first electrode 3 defines the at least one second channel 6 therein. The least one second channel 6 extends through an inner side and an outer side of the first electrode 3 and communicates with the first channel 5. The second channel 6 also extends from the first electrode 3 to a plane on which the second electrode 4 grows. Alternatively, the second channel 6 also extends from the first electrode 3 to a plane where the second electrode 4 locates.

In this implementation, the at least one second channel 6 can be but is not limited to four second channels 6. In implementations, the at least one second channel 6 can be one second channel 6, two second channels 6, three second channels 6, and five second channels 6, etc., which are not limited herein.

In this implementation, the first channel 5 has a depth which can be but not limited to the same as the second channel 6. In implementations, the second channel 6 may have a bottom which is in a slope shape. The higher end of the bottom of the second channel 6 is jointed with the bottom of the first channel 5, thereby facilitating exhaust of solder volatiles in the first channel 5 and the second channel 6. Of course, in this implementation, the cross section of the second channel 6 may have but not limited to a rectangular shape. In implementations, the cross section of the second channel 6 may also has a trapezoid shape, an arc shape, or other shapes, which is not limited herein.

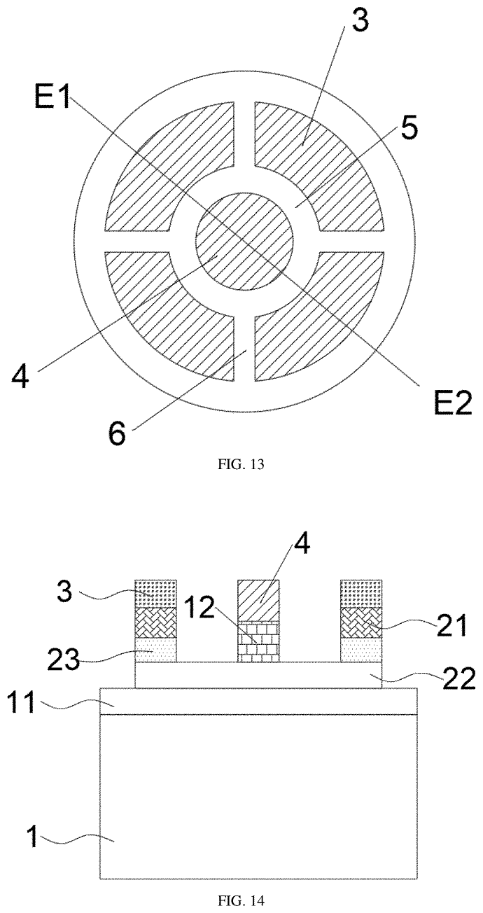

FIG. 13 is a schematic top view of the LED chip 72 according to an implementation. FIG. 14 is a schematic cross-sectional view taken along E1-E2 of FIG. 13. The difference between the LED chip 72 illustrated in FIG. 13 and the LED chip 72 illustrated in FIG. 1 includes the following.

In this implementation, the first electrode 3 is disposed on the side of the first semiconductor layer 21 away from the second semiconductor layer 22. The first electrode 3 is an N-type electrode. Correspondingly, the first semiconductor layer 21 is an N-type semiconductor. Each of the first electrode 3, the first semiconductor layer 21, and the quantum well layer 23 is in a ring shape. The quantum well layer 23, the first semiconductor layer 21, and the first electrode 3 are sequentially stacked on the second semiconductor layer 22. The current diffusion layer 12 is disposed below the second electrode 4. The current diffusion layer 12 is sandwiched between the second semiconductor layer 22 and the second electrode 4. The inner edge of a ring structure surrounded by the first electrode 3 and the current diffusion layer 12 close to the second electrode 4 is in contact with the outer edge of the first channel 5 away from the second electrode 4.

The second electrode 4 is disposed to a side of the second semiconductor layer 22 close to the first semiconductor layer 21. The second electrode 4 is a P-type electrode. Correspondingly, the second semiconductor layer 22 is a P-type semiconductor. The second electrode 4 is located within the region surrounded by the inner peripheral wall of the first electrode 3. The geometric center of the second electrode 4 coincides with the geometric center of the outer edge or the inner edge of the first electrode 3. In another implementation, the geometric center of the top surface of the second electrode 4 coincides with the geometric center of the top surface of the first electrode 3. The end of the first electrode 3 away from the first semiconductor layer 21 and the end of the second electrode 4 away from the second semiconductor layer 22 are located on the same plane.

The annular first channel 5 is defined between the first electrode 3 and the second electrode 4. The first electrode 3 defines the at least one second channel 6 therein. The least one second channel 6 extends through an inner side and an outer side of the first electrode 3 and communicates with the first channel 5. The second channel 6 also extends from the first electrode 3 to a plane on which the second electrode 4 grows. Alternatively, the second channel 6 also extends from the first electrode 3 to a plane where the second electrode 4 locates.

In this implementation, the at least one second channel 6 can be but is not limited to four second channels 6. In implementations, the at least one second channel 6 can be one second channel 6, two second channels 6, three second channels 6, and five second channels 6, etc., which are not limited herein.

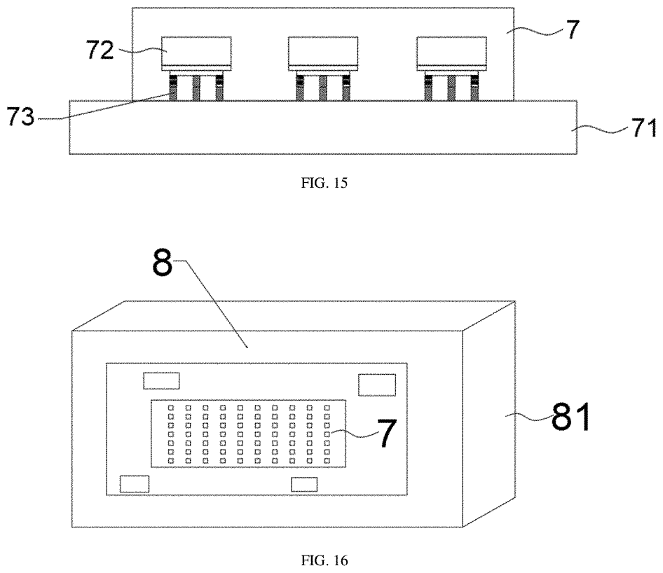

FIG. 15 is a schematic view of the display panel 7 including the LED chip 72 illustrated in FIG. 1. The display panel 7 includes the backplane 71 and the above-mentioned multiple LED chips 72. The backplane 71 is provided with a bonding electrode 73 matched with the first electrode 3 and the second electrode 4 of the LED chip 72. The LED chip 72 is flip-mounted on the backplane 71 after being bonded with the bonding electrode 73 through the first electrode 3 and the second electrode 4. The display panel 7 can be applied to display devices such as mobile phones, computers, televisions, and smart wearable display devices, which are not limited herein.

FIG. 16 is a schematic view of an electronic device 8 including the display panel 7 illustrated in FIG. 1. The display device includes the display panel 7 and a housing 81 for fixing the display panel 7. Understandably, the electronic device 8 has a display function. In an implementation, the display device includes but is not limited to a monitor, a television, a computer, a notebook computer, a tablet computer, a wearable device, etc.

Obviously, as will occur to those skilled in the art, the present disclosure is susceptible to various modifications and variations without departing from the spirit and principle of the present disclosure. In this way, if these modifications and variations of the present disclosure fall within the scope of the claims of the present disclosure and equivalent technologies, the present disclosure is also intended to include these modifications and variations.

The above description are merely the preferred implementations of the present disclosure, of course, the scope of the present disclosure is not limited thereto. Therefore, equivalent changes made based on the claims of the present disclosure still fall within the scope of the present disclosure.

What is claimed is:

1. A light-emitting diode (LED) chip, comprising a first semiconductor layer, a second semiconductor layer, a first electrode electrically connected with the first semiconductor layer, and a second electrode electrically connected with the second semiconductor layer, wherein
the first electrode is in an annular shape and surrounds the second electrode;
the first electrode and the second electrode cooperate to define a first channel therebetween, the first channel being in an annular shape; and
the first electrode defines at least one second channel therein, the at least one second channel extends through an inner side and an outer side of the first electrode and communicates with the first channel.

2. The LED chip of claim 1, wherein the first electrode is disposed on a side of the first semiconductor layer close to the second semiconductor layer.

3. The LED chip of claim 2, wherein
the first semiconductor layer is an N-type semiconductor, the second semiconductor layer is a P-type semiconductor, the first electrode is an N-type electrode, and the second electrode is a P-type electrode; and
the LED chip further comprises a current diffusion layer located between the P-type electrode and the P-type semiconductor.

4. The LED chip of claim 1, wherein the second electrode is disposed on a side of the second semiconductor layer away from the first semiconductor layer.

5. The LED chip of claim 4, wherein
the first semiconductor layer is a P-type semiconductor, the second semiconductor layer is an N-type semiconductor, the first electrode is a P-type electrode, and the second electrode is an N-type electrode; and
the LED chip further comprises a current diffusion layer located between the P-type electrode and the P-type semiconductor.

6. The LED chip of claim 1, further comprising a quantum well layer, the quantum well layer being located between the first semiconductor layer and the second semiconductor layer.

7. The LED chip of claim 5, wherein the second channel extends from the first electrode to one or more layers below the first electrode.

8. The LED chip of claim 1, wherein an end of the first electrode away from the first semiconductor layer and an end of the second electrode away from the second semiconductor layer are located on the same plane.

9. The LED chip of claim 1, wherein a geometric center of a top surface of the second electrode coincides with a geometric center of a top surface of the first electrode.

10. The LED chip of claim 1, wherein each of the first electrode and the second electrode is a metal reflective electrode.

11. A display panel, comprising a backplane and a plurality of LED chips mounted on the backplane, wherein
each of the plurality of LED chips comprises a first semiconductor layer, a second semiconductor layer, a first electrode electrically connected with the first semiconductor layer, and a second electrode electrically connected with the second semiconductor layer;
the first electrode is in an annular shape and surrounds the second electrode;
the first electrode and the second electrode cooperate to define a first channel there between, the first channel being in an annular shape; and
the first electrode defines at least one second channel therein, the at least one second channel extends through an inner side and an outer side of the first electrode and communicates with the first channel.

12. The display panel of claim 11, wherein the backplane is provided with a bonding electrode matched with the first electrode and the second electrode of the LED chip, the LED chip is flip-mounted on the backplane after being bonded with the bonding electrode through the first electrode and the second electrode.

13. The display panel of claim 11, wherein the first electrode is disposed on a side of the first semiconductor layer close to the second semiconductor layer.

14. The display panel of claim 13, wherein the first semiconductor layer is an N-type semiconductor, the second semiconductor layer is a P-type semiconductor, the first electrode is an N-type electrode, and the second electrode is a P-type electrode; and
the LED chip further comprises a current diffusion layer located between the P-type electrode and the P-type semiconductor.

15. The display panel of claim 11, wherein the second electrode is disposed on a side of the second semiconductor layer away from the first semiconductor layer.

16. The display panel of claim 15, wherein
the first semiconductor layer is a P-type semiconductor, the second semiconductor layer is an N-type semiconductor, the first electrode is a P-type electrode, and the second electrode is an N-type electrode; and
the LED chip further comprises a current diffusion layer located between the P-type electrode and the P-type semiconductor.

17. An electronic device, comprising a housing and a display panel disposed on the housing, the display panel comprises a backplane and a plurality of LED chips mounted on the backplane, wherein
each of the plurality of LED chips comprises a first semiconductor layer, a second semiconductor layer, a first electrode electrically connected with the first semiconductor layer, and a second electrode electrically connected with the second semiconductor layer;
the first electrode is in an annular shape and surrounds the second electrode;
the first electrode and the second electrode cooperate to define a first channel there between, the first channel being in an annular shape; and
the first electrode defines at least one second channel therein, the at least one second channel extends through an inner side and an outer side of the first electrode and communicates with the first channel.

18. The electronic device of claim 17, wherein the backplane is provided with a bonding electrode matched with the first electrode and the second electrode of the LED chip, the LED chip is flip-mounted on the backplane after being bonded with the bonding electrode through the first electrode and the second electrode.

19. The electronic device of claim 17, wherein
the first electrode is disposed on a side of the first semiconductor layer close to the second semiconductor layer;
the first semiconductor layer is an N-type semiconductor, the second semiconductor layer is a P-type semiconductor, the first electrode is an N-type electrode, and the second electrode is a P-type electrode; and
the LED chip further comprises a current diffusion layer located between the P-type electrode and the P-type semiconductor.

20. The electronic device of claim 17, wherein
the second electrode is disposed on a side of the second semiconductor layer away from the first semiconductor layer;
the first semiconductor layer is a P-type semiconductor, the second semiconductor layer is an N-type semiconductor, the first electrode is a P-type electrode, and the second electrode is an N-type electrode; and
the LED chip further comprises a current diffusion layer located between the P-type electrode and the P-type semiconductor.
